(19) United States
(12) Patent Application Publication
(10) Pub. No.: US 2008/0302701 A1
(43) Pub. Date: Dec. 11, 2008

(54) RETICLE POD AND RETICLE TRANSPORT POD

(76) Inventor: Po-Shin LEE, Shulin City (TW)

Correspondence Address: SINORICA, LLC, 528 FALLSGROVE DRIVE, ROCKVILLE, MD, 20850, US

(21) Appl. No.: 12/134,257

(22) Filed: Jun. 6, 2008

(30) Foreign Application Priority Data
Jun. 8, 2007 (TW) 096209425

(51) Int. Cl. B65D 90/46; H05K 9/00; H01L 21/60

(52) U.S. Cl. 206/719

(57) ABSTRACT

The present invention provides a reticle pod preventing particles in the environment from contaminating the reticle and preventing statistic electricity discharge caused by accumulated electric charge from damaging the reticle pod. The reticle pod of the present invention comprises two cover members and at least one of the cover members is made of a macromolecule material doped with metal. The metal may be stainless steel wires, conductive metal wires or metal particles.

### FIELD OF THE INVENTION

The present invention relates to a reticle pod, and particularly, the present invention relates to a reticle pod capable of preventing damages caused by static electricity discharge.

### BACKGROUND OF THE INVENTION

Semiconductor technologies have greatly improved in the past few years, and optical lithography plays an important role. Whenever it comes to pattern definition, it relies greatly on optical lithography.

The application of optical lithography on a semiconductor is to manufacture a transparent reticle with a particular shape according to a designed wiring. By exposure, the light passing through the reticle projects an image of the particular pattern of the reticle on silicon wafer. Any dust or particles, such as micro-particles, powder dust or organic materials, attached on the reticle may affect the quality of the projected image. The reticle, therefore, used for generating the pattern is required absolutely clean. Besides, in the manufacturing process of the wafer, a clean room environment is also needed to prevent the particles in the air from contaminating the wafer. However, conventional clean rooms cannot keep an absolutely dust-free environment. Current semiconductor manufacturing processes utilize a reticle pod capable of preventing contamination instead for reticle storage and transport so as to maintain the reticle as clean as possible.

The conventional reticle pods are mostly made of macromolecule material. Such macromolecule material has the advantages of easy molding, low-cost and transparency. Such macromolecule material, which is insulating and has high resistance, is liable to generate static electricity after rubbed or peeled. Especially in the working environment of a clean room wherein low humidity is always required, a reticle pod made of such macromolecule material would easily generate and then accumulate electric charges. The static electricity on the surface of the reticle is apt to attract those particles mentioned above in the air. It may be even worse. The accumulative electric charges may induce electrostatic discharges (ESD) effect occurring upon the metal wires of the reticle. Transient electric currents generated by sudden and momentary electrostatic discharge may induce sparks or arcs. When sparks or arcs occur, the resultant powerful currents along with high temperature may cause oxidation and/or melt of the metal wires, thereby destroying the pattern on the reticle.

There are many ways to solve the aforementioned problems of the electrostatic discharge. One way is firstly to maintain the humidity of the working environment in the air at an appropriate level. The personnel also have to wear clothes with grounding effect and an ion fan is necessary to diminish the static electricity in the environment. However, the aforementioned changes may incur many other unpredictable factors, and these changes may not completely eliminate those causations of reticle damages resulted from the static electricity.

Another way is to use an alternative material for making the reticle pod. The U.S. Pat. No. 6,513,654 disclosed a reticle supporting element provided with a grounding function. When the reticle pod is in contact with a station, the reticle supporting element may serve to conduct the electric charges on the reticle to elsewhere. Additionally, the U.S. Pat. No. 6,247,599 disclosed a way to provide a conductive panel on the bottom, the cover or the handle of a reticle pod so as to diminish the accumulation of the electric charge. However, those methods mentioned above all rely on the grounding effect of conductive elements to release the electric charges. Such methods cannot prevent the direct accumulation of the electric charges on the reticle pod.

If the material used for making the reticle pod becomes a conductive material, then the problems of accumulation of static electricity can be eliminated. However, when the material of the reticle pod is changed to a conductive metal material, the corresponding machine interface will also need to be changed, thereby increasing the manufacturing cost.

In view of the above disadvantages, the present invention provides a reticle pod to overcome those aforementioned problems.

### SUMMARY OF THE INVENTION

In order to solve the problems mentioned above, the recticle pod of the present invention is made of a macromolecule material doped with metal therein. When even the electric charges build-up on the the macromolecule material due to friction, the metal material in the vicinity will immediately conduct the electric charges to elsewhere, thereby preventing the accumulation of the electric charges and the electrostatic discharge effect.

One object of the present invention is to provide a reticle pod capable of diminishing the accumulation of electric charges and preventing the static electricity from damaging the reticle.

Another object of the present invention is to provide a reticle pod that is made of a macromolecule material doped with metal therein in which the material possesses both advantages of macromolecule material and metal, such as low-cost, easy molding, and transparency.

Yet another object of the present invention is to provide a reticle pod that is made of a macromolecule material doped with metal therein, in which the material can continuously conduct the electric charges to elsewhere so as to prevent the damages of reticle caused by the high temperate resulted from sudden and momentary electrostatic discharge.

### BRIEF DESCRIPTION OF THE DRAWINGS

FIG. 1 is a cross sectional view of the recticle pod of a preferred embodiment in accordance with the present invention.

FIG. 2 is a cross sectional view of the recticle pod of another preferred embodiment in accordance with the present invention.

FIG. 3 is a cross sectional view of the recticle pod of yet another preferred embodiment in accordance with the present invention.

### DETAILED DESCRIPTION OF THE EMBODIMENTS

The present invention discloses a reticle pod, wherein the used basic elements and the connecting methods have been disclosed in detail in the background section and will not be described hereinafter. The basic structure of the reticle pod should be known by those skilled in the art and thus will not be described in details. The accompanying drawings illustrate a schematic view of the features of the present invention and are not drawn to scale.

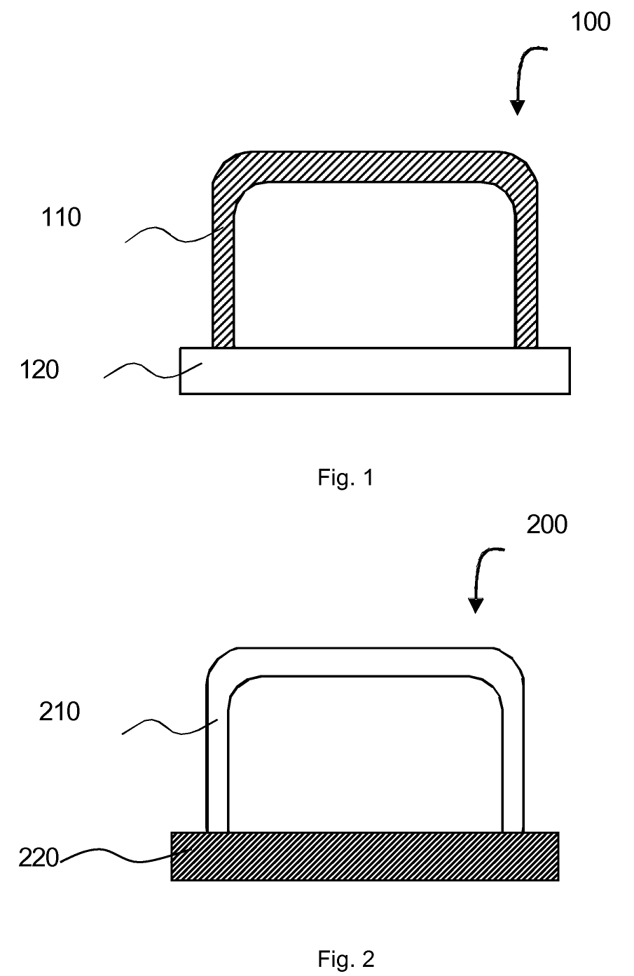

Referring to FIG. 1, a reticle pod 100 is provided in accordance with a preferred embodiment of the present invention. The reticle pod 100 may be a reticle storage pod or a reticle transport pod. The reticle pod 100 includes a first cover member 110 and a second cover member 120. The second cover member 120 forms an inner space with said first cover member 110 for accommodating at least one reticle (not shown) therein. The first cover member 110 is made of a macromolecule material doped with metal. Said metal may be stainless steel wires, conductive metal wires or metal particles.

Referring to FIG. 2, a reticle pod 200 is provided in accordance with another preferred embodiment of the present invention. The reticle pod 200 may be a reticle storage pod, or a reticle transport pod. The reticle pod 200 includes a first cover member 210 and a second cover member 220. The second cover member 220 forms an inner space with said first cover member 210 for accommodating at least one reticle (not shown) therein. The second cover member 220 is made of a macromolecule material doped with metal. Said metal may be stainless steel wires, conductive metal wires or metal particles.

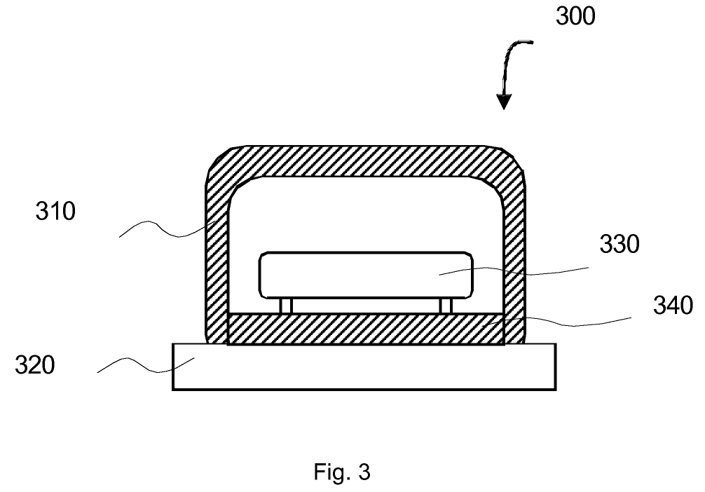

Referring to FIG. 3, a reticle pod 300 is provided in accordance with yet another preferred embodiment of the present invention. The reticle pod 300 may be a reticle storage pod or a reticle transport pod. The reticle pod 300 includes a base cover member 320 and a top cover member 310. The base cover member 320 is made of metal, stainless steel or a macromolecule material. The base cover member 320 together with the top cover member 310 forms an inner space which is capable of accommodating at least one reticle 330. The top cover member 310 and/or the base cover member 320 could be made of a macromolecule material doped with metal therein. Said metal may be stainless steel wires, conductive metal wires or metal particles. Additionally, a conductive panel 340 which is made of metal is mounted on a top surface of the base cover member 320 facing the top cover member 310 and is electrically connected to the top cover member 310.

Besides, the surface resistance of the macromolecule material doped with metal therein as mentioned above preferably ranges from about 10³ to about 10⁹ ohm/sq.

In summary, the reticle pod of the present invention is made of the macromolecule material doped with metal therein. Such material has the advantages of both those of macromolecule and metal and can continuously conduct electric charges to elsewhere, thereby preventing the damages of reticle resulted from the heat caused by the sudden and momentary electrostatic discharges. The disclosed subject matter invention is cheap in cost, easy to mold and able to be made as a transparent article.

The present invention has already been disclosed through the preferred embodiments and the accompanying drawings. However, those skilled in the art should understand that the embodiments of the present invention are not meant to limit the scope of the present invention and do not leave the spirit and scope of the present invention. Modification and variation of the elements of the present invention are covered by the present invention. The present invention is set forth in the following claims.

What is claimed is:

1. A reticle pod, comprising:
a first cover member; and
a second cover member forming an inner space with said first cover member for accommodating at least one reticle therein, in which said first or second cover member is made of a macromolecule material doped with metal therein.

2. The reticle pod of claim 1, wherein said metal is doped in said macromolecule material in a form of metal wires.

3. The reticle pod of claim 1, wherein said metal is doped in said macromolecule material in a form of metal particles.

4. The reticle pod of claim 1, wherein said metal is stainless steel material.

5. The reticle pod of claim 1, wherein said reticle pod is a reticle storage pod.

6. The reticle pod of claim 1, wherein said reticle pod is a reticle transport pod.

7. The reticle pod of claim 1, wherein said macromolecule material doped with metal has a surface resistance ranging from about 10³ to about 10⁹ ohm/sq.

8. A reticle transport pod, comprising:
a base cover member; and
a top cover member, forming an inner space with said base cover member for accommodating at least one reticle therein, in which said top cover member or said base cover member is made of a macromolecule material doped with metal.

9. The reticle transport pod of claim 8, further comprising a conductive panel provided in a predetermined area on a top surface of said base cover member facing said top cover member.

10. The reticle transport pod of claim 9, wherein said top cover member and said conductive panel are electrically connected.

11. The reticle transport pod of claim 8, wherein said metal is doped in said macromolecule material in a form of metal wires.

12. The reticle transport pod of claim 8, wherein said metal is stainless steel.

13. The reticle transport pod of claim 8, wherein said metal is doped in said macromolecule material in a form of metal particles.

14. The reticle transport pod of claim 8, wherein said conductive panel is made of metal.

15. The reticle transport pod of claim 8, wherein said conductive panel is made of stainless steel.

16. The reticle transport pod of claim 8, wherein said base cover member is made of a macromolecule material.

17. The reticle transport pod of claim 8, wherein said base cover member is made of metal.

18. The reticle transport pod of claim 8, wherein said base cover member is made of stainless steel.
